(19) United States
(12) Patent Application Publication
(10) Pub. No.: US 2014/0124124 A1
(43) Pub. Date: May 8, 2014

(54) PRINTED CIRCUIT BOARD MANUFACTURING METHOD

(71) Applicant: BOARDTEK ELECTRONICS CORPORATION, Taoyuan (TW)

(72) Inventor: CHIEN-CHENG LEE, TAOYUAN (TW)

(73) Assignee: BOARDTEK ELECTRONICS CORPORATION, TAOYUAN (TW)

(21) Appl. No.: 13/671,739

(22) Filed: Nov. 8, 2012

(51) Int. Cl. H05K 3/10; H05K 3/36

(52) U.S. Cl. CPC H05K 3/107; H05K 3/36
USPC 156/150; 205/125

(57) ABSTRACT

This invention discloses a printed circuit board manufacturing method capable of manufacturing circuits with at least two different thicknesses on a same PCB substrate. In the printed circuit board manufacturing method, a circuit trench is formed on a first PCB substrate having a copper clad circuit layer of a smaller thickness and exposed from the bottom of a groove on another side of the copper clad layer, and then a thick copper is filled into the circuit trench by a copper electroplating method, and then a printed circuit board manufacturing flow is adopted to manufacture the printed circuit board having the circuits with at least two different thicknesses on the first PCB substrate, so as to achieve the effect of saving material costs, avoiding a waste of high priced metals, and reducing pollution sources.

### BACKGROUND OF THE INVENTION

1. Field of the Invention

The present invention relates to a circuit manufacturing technology for printed circuit boards, and more particularly to the printed circuit board manufacturing method applicable for manufacturing circuits with at least two different thicknesses on a same PCB substrate.

2. Description of Related Art

As we all know, a printed circuit board (PCB) generally uses a circuit layer (or a copper film) for transmitting electric signals and plays the role of connecting circuits between electronic components, integrating the circuits on a plane and distributing the circuits on a board surface or a three-dimensional circuit layer of the printed circuit board to constitute a network for connecting components at different positions.

In general, most basic materials (hereinafter referred to as “substrates” of a printed circuit board are laminates formed by stacking and laminating an insulating paper, a fiberglass fabric or any other fiber material with a prepreg which is soaked with a resin, and added with a copper film on a single side or both sides of the printed circuit board at high temperature and pressure. As to the conductor that constitutes each circuit layer of the printed circuit board, a copper plating guide hole is provided for achieving the effect.

As the material and manufacturing technologies advance rapidly, the performance of the printed circuit board becomes relatively more reliable, thus the printed circuit board can be used extensively in different areas or even becomes one of the necessary key components. For example, the printed circuit board is applied more and more in spotlighted electric vehicles for related circuit layout design that integrates control signals and driving current, and the key technology mainly manufactures circuits of different thicknesses on a substrate of a printed circuit board for transmitting the control signals by using the circuit with relatively smaller thickness and transmitting high-power driving current by the circuit with relatively greater thickness in order to reduce the impedance of the driving current and avoid overheat of the printed circuit board that may lower the operation performance.

In the conventional manufacturing technology for manufacturing circuits of two different thicknesses on a PCB substrate, a PCB substrate having a copper clad on a surface of the PCB substrate is adopted, wherein the height of the copper clad must be greater than the maximum thickness of the circuit thickness, and after the circuit etching operation of the copper clad formed on the surface of the PCB substrate is completed, the portion of the copper clad not required on the circuit is removed to obtain the circuits of different thicknesses.

However, the aforementioned manufacturing method is simply called the “addition and subtraction manufacturing technology” in the industry, the manufacturing process for producing different heights not only wastes a large quantity of high priced metals, but also requires repeated executions of wet process that consumes much more energies and generates pollution sources. Particularly, the circuits of different thicknesses have a significant height difference at the surface of the printed circuit board which may affect the manufacturing effect of the later surface treatment or even results in a dislocation of the components and a low manufacturing quality.

### SUMMARY OF THE INVENTION

In view of the aforementioned drawbacks of the prior art, the present invention provides a printed circuit board manufacturing method capable of lowering the material costs and manufacturing circuits with different thicknesses on a same PCB substrate.

To achieve the aforementioned objective, the present invention provides a printed circuit board manufacturing method, comprising the steps of: (a) providing a first PCB substrate having at least one copper clad circuit layer; (b) forming a circuit trench on the first PCB substrate and opposite to another side of the copper clad circuit layer and exposed from the bottom of a groove on at least one side of the copper clad circuit layer; (c) filling a thick copper into the circuit trench by a copper electroplating method; wherein the circuit board obtained by carrying out the steps (a) to (c) includes at least one circuit comprised of the copper clad circuit layer and formed on a same first PCB substrate, and at least one circuit comprised of a thick copper electroplated in the circuit trench and embedded into a board surface of the first PCB substrate.

With the foregoing technical characteristics, at least one circuit with a thickness greater than that of the copper clad circuit layer can be constructed on the first PCB substrate under the basic circuit structure having a copper clad circuit layer with a smaller thickness, so as to achieve the effects of saving material costs, avoiding a waste of high priced metals, and reducing pollution sources.

More specifically, the printed circuit board manufacturing method of the present invention has the following advantages:

1. In the first PCB substrate of the basic structure of the circuit with the copper clad circuit layer of a smaller thickness, at least one circuit with a thickness greater than that of the copper clad circuit layer is manufactured to save the material costs.

2. The addition manufacturing technology is applied to build the circuit having a circuit with a thickness greater than that of the copper clad circuit layer on the first PCB substrate, so as to avoid wasting the high priced metal effectively.

3. In the addition manufacturing technology is applied to build the circuit having a circuit with a thickness greater than that of the copper clad circuit layer on the first PCB substrate, the manufacture does not require repeated etching operations, so that the pollution sources can be minimized.

4. Since the main circuit with a greater thickness that that of the copper clad circuit layer is penetrated deeply into the board surface of the first PCB substrate, therefore when a multiple of layers are laminated, the process no longer requires a large quantity of filling of the prepreg, so that the issues of sliding boards or bubbles caused by excessive or insufficient flow will not occur easily during the lamination process, or a large quantity of resin flows into the gaps of the thick copper to give rise to the issues of reliability or CAF caused by the direct contact of the copper clad layer.

5. Since the main circuit with a greater thickness that that of the copper clad circuit layer is penetrated deeply into the board surface of the first PCB substrate, therefore the problem of having a height difference will not be so serious, that may make it difficult to cover a solder mask or print texts.

### BRIEF DESCRIPTION OF THE DRAWINGS

FIG. 1 is a basic flow chart of the present invention;

FIG. 2 is a cross-sectional view of a first PCB substrate of a first preferred embodiment of the present invention;

FIG. 3 is a cross-sectional view of a circuit trench formed on a board surface of a first PCB substrate of the present invention;

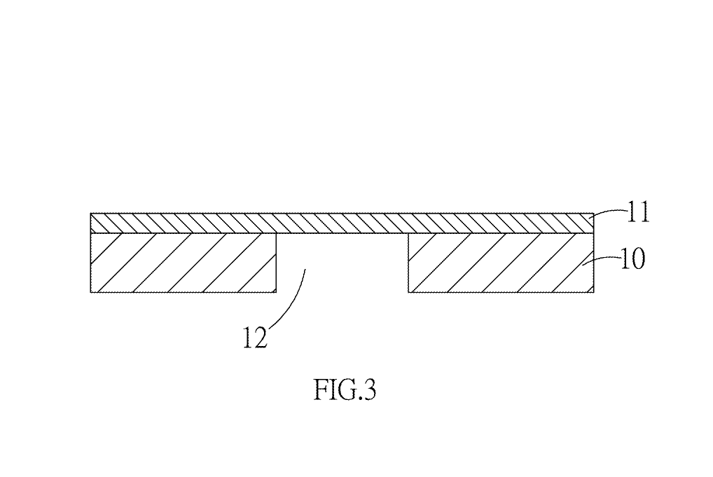

FIG. 4 is a cross-sectional view of a thick copper filled and coated into a circuit trench of a first PCB substrate of the present invention;

FIG. 5 is a schematic view of stacking and laminating a plurality of first PCB substrates of the present invention;

FIG. 6 is a cross-sectional view of a plurality of stacked and laminated first PCB substrates of the present invention;

FIG. 7 is a schematic view of stacking and laminating a first PCB substrate and a second PCB substrate of the present invention;

FIG. 8 is a cross-sectional view of stacked and laminated first and second PCB substrates of the present invention;

FIG. 9 is a cross-sectional view of another structure of the stacked and laminated first and second PCB substrates of the present invention;

FIG. 10 is a cross-sectional view of a first PCB substrate in accordance with another preferred embodiment of the present invention; and

FIG. 11 is a cross-sectional view of a metal film with a predetermined thickness constructed on a wall of a circuit trench of a first PCB substrate of the present invention.

### DETAILED DESCRIPTION OF THE PREFERRED EMBODIMENTS

The technical contents and characteristics of the present invention will be apparent with the detailed description of a preferred embodiment accompanied with related drawings as follows.

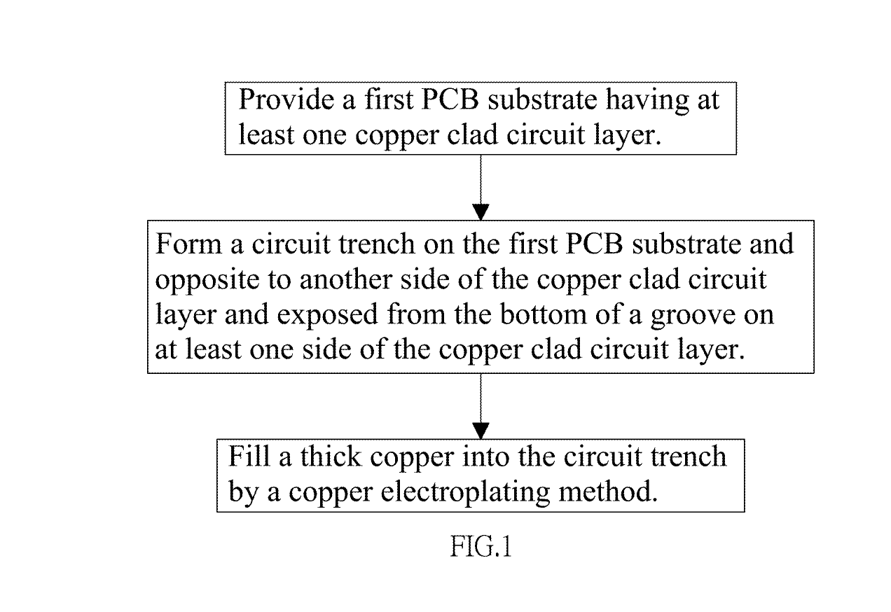

With reference to FIG. 1 for the flow chart of the present invention, the printed circuit board manufacturing method of the present invention comprises the steps of:

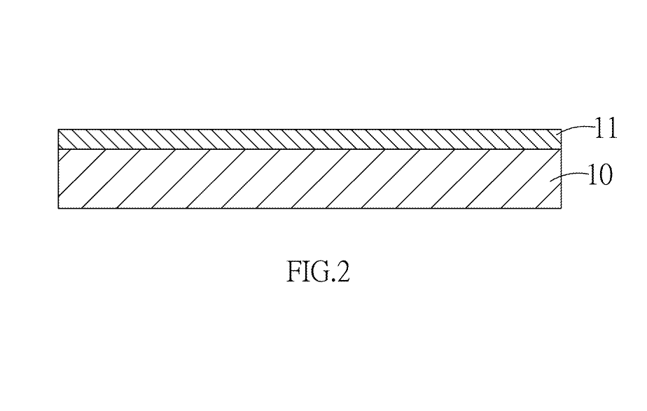

(a) providing a first PCB substrate 10 having at least one copper clad circuit layer 11 as shown in FIG. 2, wherein the first PCB substrate 10 has a copper clad circuit layer 11 disposed on one of the board surfaces or two copper clad layers 11 disposed on two board surfaces respectively.

(b) On the other side of the first PCB substrate 10 opposite to the copper clad circuit layer 11, at least one circuit trench 12 is formed on the copper clad circuit layer 11 on the other side or exposed from the bottom of the groove.

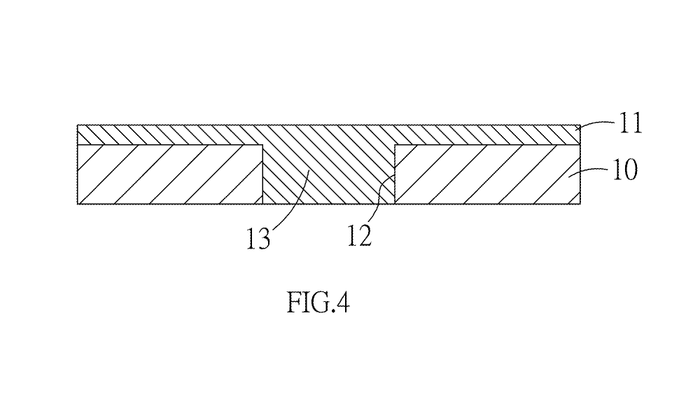

(c) The thick copper 13 is filled into the circuit trench 12 by a copper electroplating method as shown in FIG. 4.

Basically, the circuit board obtained from the aforementioned steps (a) to (c) in accordance with the printed circuit board manufacturing method of the present invention can have circuits with at least two different thicknesses circuit (wherein one of the circuits is comprised of the copper clad circuit layer 11, and the other circuit is comprised of a thick copper electroplated in the circuit trench 12 and embedded into a board surface of the first PCB substrate 10) on a same PCB substrate 10. During an application, the circuit with a smaller thickness (which is the circuit comprised of the copper clad circuit layer 11) is used for transmitting control signals (or digital control signals) and the circuit with the greater thickness (which is the circuit embedded into the board surface of the first PCB substrate 10) to transmit high-power driving current, so as to achieve the effects of reducing the impedance of the driving current, avoiding burning or damages of the circuit, or overheating the printed circuit board that may lower the operation performance.

In the use of the printed circuit board manufactured by the present invention, the circuit with the greater thickness (embedded into the board surface of the first PCB substrate 10) is used as a waste heat emission channel of the circuit board, so that the circuit board always maintains its operation performance. Particularly, the present invention with the aforementioned technical characteristics can manufacture at least one circuit with a thickness greater than that of the copper clad circuit layer on the first PCB substrate in the basic structure of the copper clad circuit layer with a smaller a thickness, so as to achieve the effects of saving material costs, avoiding a waste of high priced metals, and reducing pollution sources.

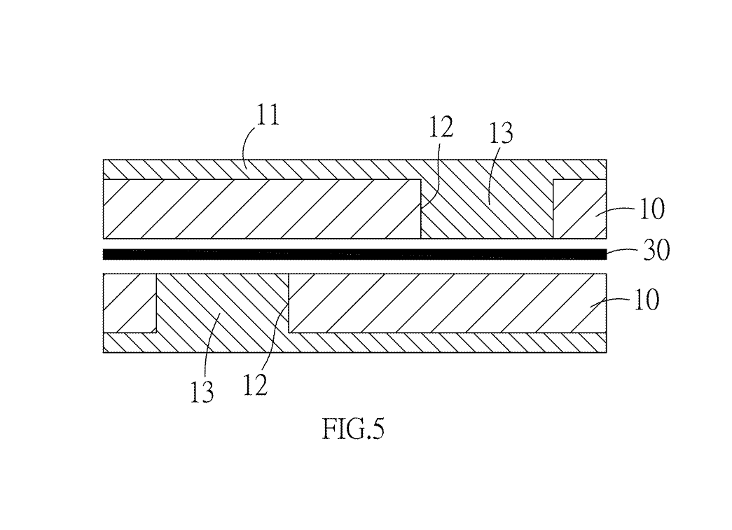

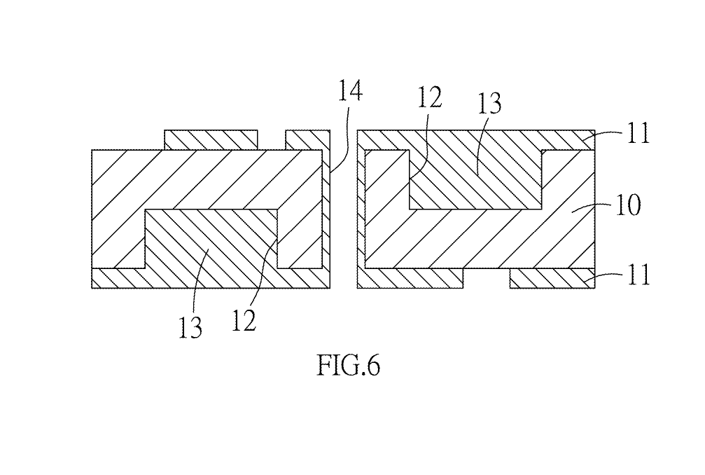

In addition, the present invention provide a printed circuit board with a plurality of copper clad circuit layers 11, besides the feature of having the copper clad circuit layers on both board surfaces respectively, so as to increase the circuit layout density. In FIG. 5, at least two first PCB substrates 10 obtained by carrying out the steps (a) to (c) of the manufacturing process are further stacked and laminated (wherein the prepreg 30 as shown in the figure is formed by stacking and laminating the plurality of first PCB substrates 10) in the present invention. In FIG. 6, at least one conductor 14 is installed between the first PCB substrates 10 to connect predetermined circuits to provide a multi-layer circuit board to similarly achieve the effect of increasing the circuit layout density.

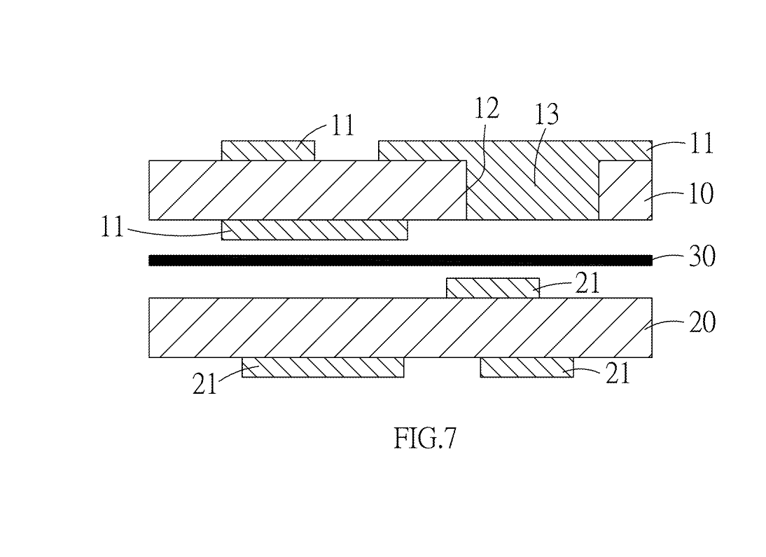

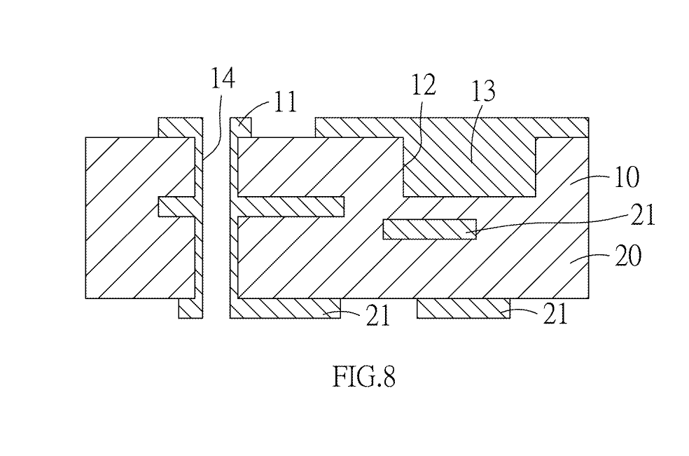

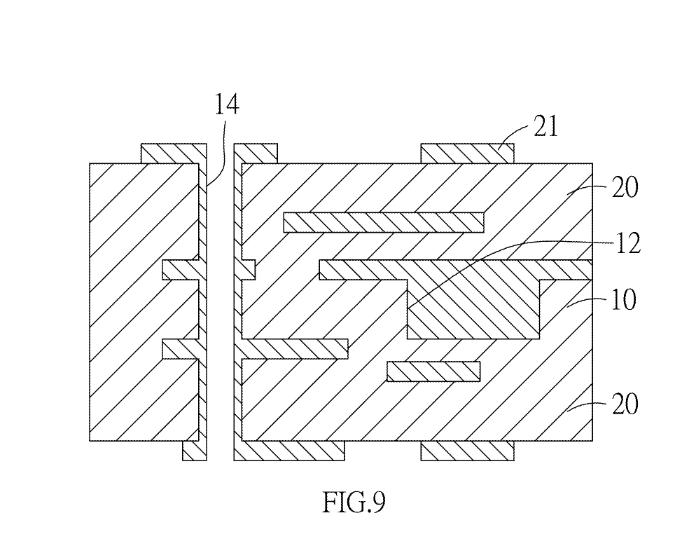

In FIG. 7, at least one second PCB substrate 20 further has at least one copper clad circuit layer 21, and at least one first PCB substrate 10 obtained by carrying out the steps (a) to (c) of the manufacturing process is stacked and laminated with the second PCB substrate 20 (wherein the first PCB substrate 10 and the second PCB substrate 20 of the prepreg 30 as shown in the figure are stacked and laminated). In FIG. 8, at least one conductor 14 is installed between the first circuit board 10 and the second PCB substrate 20 to connect predetermined circuits to achieve the effect of increasing the circuit layout density. In FIG. 9, the circuit formed by filling the thick copper 13 into the circuit trench 12 and embedded into a board surface of the first PCB substrate 10 can be hidden completely into an inner layer of the board formed by laminating the first circuit board 10 and the second PCB substrate 20 and used as a waste heat emission channel of the printed circuit board for maintaining the normal operation performance of the printed circuit board.

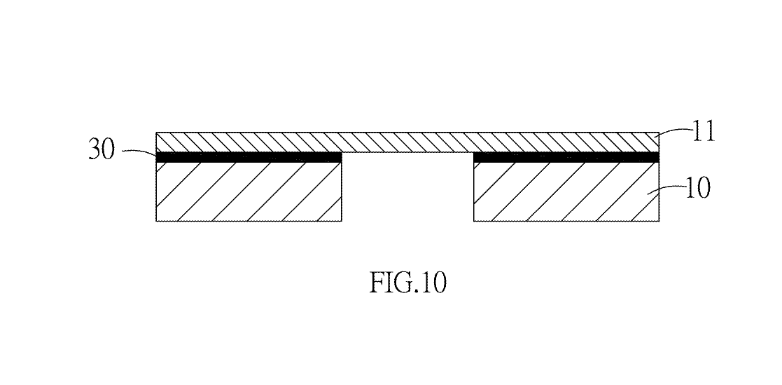

Since the main circuit with a thickness greater than that of the copper clad circuit layer 11 is embedded into a board surface of the first PCB substrate 10, therefore a large quantity of the filling of the prepreg is no longer required for laminating a plurality of boards during the manufacture, and the issues of slippery boards and bubbles caused by excessive or insufficient resin, and a large quantity of resin flowing into the gaps of the thick copper can be overcome to improve the reliability or CAF problem due to the direct contact of the fiberglass with the copper clad layer. In other words, the first PCB substrate 10 of the present invention has the copper clad circuit layer 11 formed on the board surface of the first PCB substrate 10 by a copper plating method or by a laminating method (as shown in FIG. 10, wherein the copper clad circuit layer 11 is fixed onto the first PCB substrate 10 in the prepreg 30) in order to obtain high quality and reliability of the circuits.

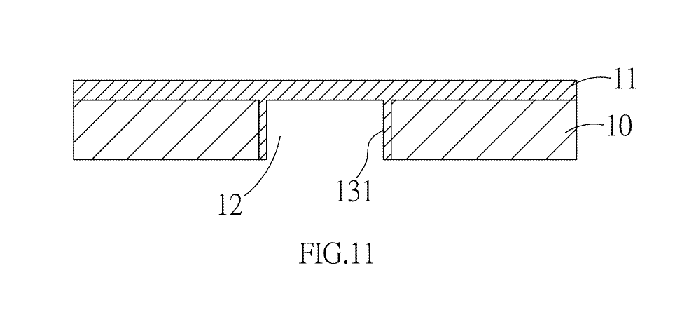

Before the thick copper is filled into the circuit trench, a metal film 131 with a predetermined thickness is constructed on an inner wall of the circuit trench 12 as shown in FIG. 11 after the first PCB substrate 10 is processed as described in the step (b), and then the thick copper 13 is filled into the circuit trench 12 by a copper electroplating method (as shown in FIG. 4) to improve the quality of filling and coating the thick copper 13.

Regardless of the design with a copper clad circuit layer on a single side the first PCB substrate 10 or two copper clad circuit layers on both sides of the first PCB substrate 10 respectively, a masking layer is coated onto a surface of the copper clad circuit layer after the first PCB substrate 10 is processed as described in the step (b) completed, and then thick copper is filled into the circuit trench by a copper electroplating method, and the masking layer on the surface of the copper clad circuit layer is removed after the steps (c) ends, so that the copper clad circuit layer can be protected from increasing its thickness caused by the coating of the electroplated metal in the process of filling the thick copper.

Compared with the prior art, the printed circuit board manufacturing method of the present invention has the following advantages:

1. In the first PCB substrate of the basic structure of the circuit with the copper clad circuit layer of a smaller thickness, at least one circuit with a thickness greater than that of the copper clad circuit layer is manufactured to save the material costs.

2. The addition manufacturing technology is applied to build the circuit having a circuit with a thickness greater than that of the copper clad circuit layer on the first PCB substrate, so as to avoid wasting the high priced metal effectively.

3. In the addition manufacturing technology is applied to build the circuit having a circuit with a thickness greater than that of the copper clad circuit layer on the first PCB substrate, the manufacture does not require repeated etching operations, so that the pollution sources can be minimized.

4. Since the main circuit with a greater thickness that that of the copper clad circuit layer is penetrated deeply into the board surface of the first PCB substrate, therefore when a multiple of layers are laminated, the process no longer requires a large quantity of filling of the prepreg, so that the issues of sliding boards or bubbles caused by excessive or insufficient flow will not occur easily during the lamination process, or a large quantity of resin flows into the gaps of the thick copper to give rise to the issues of reliability or CAF caused by the direct contact of the copper clad layer.

5. Since the main circuit with a greater thickness that that of the copper clad circuit layer is penetrated deeply into the board surface of the first PCB substrate, therefore the problem of having a height difference will not be so serious, that may make it difficult to cover a solder mask or print texts.

In summation of the description above, the present invention provides a feasible printed circuit board manufacturing method, improves over the prior art, and complies with the patent application requirements, and thus is duly filed for patent application. While the invention has been described by means of specific embodiments, numerous modifications and variations could be made thereto by those skilled in the art without departing from the scope and spirit of the invention set forth in the claims.

What is claimed is:

1. A printed circuit board manufacturing method, comprising the steps of:
(a) providing a first PCB substrate having at least one copper clad circuit layer;
(b) forming a circuit trench disposed on the first PCB substrate and opposite to another side of the copper clad circuit layer and exposed from the bottom of a groove on at least one side of the copper clad circuit layer;
(c) filling a thick copper into the circuit trench by a copper electroplating method; wherein the circuit board obtained from carrying out the steps (a) to (c) includes at least one circuit comprised of the copper clad circuit layer and formed on the same first PCB substrate, and at least one circuit comprised of a thick copper electroplated in the circuit trench and embedded into a board surface of the first PCB substrate.

2. The printed circuit board manufacturing method of claim 1, further comprising the steps of stacking and laminating at least two first PCB substrates obtained from a manufacturing process including the steps (a) to (c), and installing at least one conductor between the first circuit boards for coupling a predetermined circuit.

3. The printed circuit board manufacturing method of claim 1, further comprising the steps of providing at least one second PCB substrate having at least one copper clad circuit layer, stacking and laminating at least two first PCB substrates obtained from the manufacturing process including the steps (a) to (c), and installing at least one conductor between the first circuit boards for coupling a predetermined circuit.

4. The printed circuit board manufacturing method of claim 1, further comprising the steps of constructing a metal film with a predetermined thickness on an inner wall of the circuit trench, and then filling a thick copper into the circuit trench by a copper electroplating method, after the first PCB substrate is processed as described in the step (b).

5. The printed circuit board manufacturing method of claim 1, further comprising the steps of covering a masking layer onto a surface of the copper clad circuit layer and then filling the thick copper into the circuit trench by a copper electroplating method after the first PCB substrate is processed as described in the step (b), and removing the masking layer from the surface of the copper clad circuit after the step (c) is completed.

6. The printed circuit board manufacturing method of claim 1, wherein the copper clad circuit layer is formed on a board surface of the first PCB substrate by a copper electroplating method.

7. The printed circuit board manufacturing method of claim 1, wherein the copper clad circuit layer is formed on a board surface of the first PCB substrate by a laminating method.
